(19) United States
(12) Patent Application Publication
(10) Pub. No.: US 2011/0298343 A1
(43) Pub. Date: Dec. 8, 2011

(54) ACTUATOR MODULE HAVING UNIVERSAL COMBINATION STRUCTURE

(75) Inventors: Byoung Soo KIM, Seoul (KR); Jung Ho Lee, Gwangmyeong (KR)

(73) Assignee: ROBOTIS CO., LTD., Seoul (KR)

(21) Appl. No.: 13/009,747

(22) Filed: Jan. 19, 2011

(30) Foreign Application Priority Data
Jun. 4, 2010 (KR) 10-2010-0052971

(51) Int. Cl. H05K 5/02

(52) U.S. Cl. 312/223.6; 312/223.1

(57) ABSTRACT

The present invention relates to an actuator module with universal combination structure. The actuator module with universal combination structure comprises a first fixture that is installed on the actuator module itself for connection with a coupling element, and the coupling element having a second fixture that corresponds to the first fixture, and users can make various forms of combination structure by using bolts and nuts.

### BACKGROUND OF THE INVENTION

The present invention relates to a polyarticular robot and in particular to an actuator module being able to connect universally. Users can make various forms of combination structure by using coupling elements, bolts and nuts.

Robots known as personal robots provide various services at homes, medical institutes, long-term care facilities and so on. An entertainment robot is known to be one of these personal robots. Such entertainment robots are used in various areas such as playing, psychological treatment, education, etc.

Typical examples of an entertainment robot are Sony's ‘AIBO’ and robot ‘Paro’ for psychological treatment, and there are other small entertainment robots.

By the way, it is typical for such small entertainment robots to have a single fixed form and perform functions within the range of specifications designated by the manufacturer. In other words, users already recognize functions and form of a robot at the time of purchase.

However, if degree of freedom, expansion and compatibility are given to personal robots, users can variously change forms of personal robots and make personal robots to continuously perform new movements.

### SUMMARY OF THE INVENTION

It is the object of the present invention to provide an actuator module with universal combination structure that allows users to change a robot and upgrade the robot as needed.

It is a further object of the present invention to provide an actuator module with universal combination structure that allows users to make various forms of combination structure by using bolts and nuts.

It is a further object of the present invention to provide an actuator module with universal combination structure that not only makes assembly and connection of the actuator module and coupling elements easy, but also solves the wiring problems accompanied with the connection of various elements.

It is a further object of the present invention to provide an actuator module with universal combination structure that allows users to interconnect the actuator modules in various forms using the coupling elements and allows the center axes of each actuator module to be properly arranged in order not to lose the efficiency of the connections.

It is a further object of the present invention to provide an actuator module with two degrees of freedom that can design to overcome the space limitations of a polyarticular robot, reduce weight of the polyarticular robot and make the polyarticular robot slim.

The above objects have been achieved by an actuator module with universal combination structure that comprises a housing to accommodate circuit parts and a mechanical parts; at least one first fixture formed on a side and a bottom of the housing, wherein the each first fixture comprises an first aperture through which a bolt passes and a nut joining part to accommodate a nut.

In accordance with another aspect of the present invention, the actuator module with universal combination structure further comprises a horn that is connected with a drive shaft of the mechanical parts. The horn comprises a shaft connecting hole to accommodate the drive shaft at the horn's center, and at least one groove that is formed on the outer surface of the shaft connecting hole to be connected with a connecting protrusion formed the end of the drive shaft.

In accordance with another aspect of the present invention, the horn further comprises a connecting reference line formed on the top surface of the horn, at least one first bolt hole that passes through the horn, and at least one nut joining part formed on a rear surface of the horn.

In accordance with another aspect of the present invention, the housing comprises a first housing, a second housing connected with the first housing, and a third housing connected with the second housing. The first housing comprises an second aperture through which the drive shaft passes, the second housing comprises at least one bolt guide groove to accommodate an end parts of a bolt that passes through the first aperture to be coupled to the nut installed in the nut joining part, and the third housing comprises a bushing connecting part to accommodate a bushing and a connector installation part that allows a connector to be installed.

In accordance with another aspect of the present invention, the third housing further comprises a wiring guide part that guides wires to pass through the connector installation part.

In accordance with another aspect of the present invention, the actuator module with universal combination structure further comprises at least one coupling element that comprises at least one second fixture to be connected by a bolt with the first fixture formed on the side of the housing.

In accordance with another aspect of the present invention, the coupling element further comprises at least one hook that allows wires to pass through.

In accordance with another aspect of the present invention, the coupling element further comprises an anchor insertion part that allows an anchor to be inserted into.

In accordance with another aspect of the present invention, an actuator module with universal combination structure having two degrees of freedom by a first drive shaft and a second drive shaft to be perpendicular to the first drive shaft.

In accordance with another aspect of the present invention, the actuator module with universal combination structure comprises an upper housing that accommodates a first drive shaft, a second drive shaft, and first additional installation holes to be connected with bolts; a lower housing that accommodates a first motor to drive the first drive shaft, a second motor to drive the second drive shaft, and second additional installation holes to be connected with bolts; and first and second gear sets installed in the space inside the upper housing and the lower housing, wherein the first gear set delivers driving power from the first motor to the first drive shaft and the second gear set delivers the driving power from the second motor to the second drive shaft.

In accordance with another aspect of the present invention, the upper housing further comprises a first bushing connecting part to accommodate a first rotation axle of a first external coupling element, a second bushing connecting part to accommodate a second rotation axle of a second external coupling element, a first round board shaped first horn connected with a protruding end of the first drive shaft, and a second round board shaped second horn connected with a protruding end of the second drive shaft.

According to the present invention, an actuator module with universal combination structure can be used in a polyarticular robot that can be changed and upgraded by the user himself. The actuator module with universal combination structure provides a robot solution with a high degree of freedom, expansion and compatibility.

According to the present invention, users not only make the assembly and connection of the actuator module and the coupling elements easy, but also solve the wiring problems that arise when connecting various elements by adopting new designs in each part of the housing of the actuator module.

An actuator module with universal combination structure according to the present invention provides an actuator module with universal combination structure that allows the user to interconnect in various forms using the coupling elements and allows the center axes of each actuator module to be properly arranged in order not to lose the efficiency of connections.

An actuator module with universal combination structure according to the present invention provides an actuator module with two degrees of freedom that can be designed to overcome the space limitations of a polyarticular robot, reduce weight of the polyarticular robot and make the polyarticular robot slim.

### BRIEF DESCRIPTION OF THE DRAWINGS

FIG. 1 illustrates a polyarticular robot comprising actuator modules of the present invention;

FIG. 2 is a first perspective view of an embodiment of the actuator module of the present invention;

FIG. 3 is a side view of the actuator module shown in FIG. 2;

FIG. 4 is a second perspective view of the actuator module shown in FIG. 2;

FIG. 5 is a front view of the actuator module shown in FIG. 2;

FIG. 6 is a rear view of the actuator module shown in FIG. 2;

FIG. 7 illustrates a third housing of the actuator module shown in FIG. 2;

FIG. 8 is a bottom view of the actuator module shown in FIG. 2;

FIG. 9 is an internal view of the actuator module shown in FIG. 2;

FIG. 10 is a first perspective view seen from the top of another embodiment of an actuator module of the present invention;

FIG. 11 is a second perspective view seen from the bottom of the actuator module shown in FIG. 10;

FIG. 12 shows internal mechanisms of the actuator module shown in FIG. 10;

FIG. 13 shows the upper port of the actuator module shown in FIG. 10;

FIG. 14 shows wiring arrangement of the actuator module shown in FIG. 11;

FIG. 15 is a top view of a horn that connects to the actuator module of the present invention;

FIG. 16 is a bottom view of the horn shown in FIG. 15;

FIGS. 17 and 18 show a perspective view of a first coupling element that connects to the actuator module of the present invention;

FIG. 19 shows a perspective view of a second coupling element that connects to the actuator module of the present invention;

FIGS. 20 and 21 show a perspective view of a third coupling element that connects to the actuator module of the present invention;

FIGS. 22 and 23 show a perspective view of a fourth coupling element that connects to the actuator module of the present invention;

FIGS. 24 and 25 show a connecting relationship between the actuator module shown in FIG. 2 and the third coupling element shown in FIGS. 20 and 21;

FIGS. 26 and 27 show a connecting relationship between the actuator module shown in FIG. 2 and the fourth coupling element shown in FIGS. 22 and 23;

FIGS. 28 and 29 show a connecting relationship between two actuator module shown in FIG. 2 and the first coupling element shown in FIGS. 17 and 18;

FIGS. 30 and 31 show a connecting relationship between two actuator module shown in FIG. 2 and two first coupling element shown in FIGS. 17 and 18;

FIG. 32 shows a connecting relationship between an actuator module and a fifth coupling element and a sixth coupling element;

FIGS. 33 and 34 show a connecting relationship between the actuator module shown in FIG. 2 and the actuator module shown in FIG. 10; and

FIG. 35 illustrates a polyarticular robot formed by connecting the actuator module shown in FIG. 2 and the actuator module shown in FIG. 10.

### DETAILED DESCRIPTION OF THE PRESENT INVENTION

Hereinafter, the configuration of the present invention is explained with the attached drawings as reference.

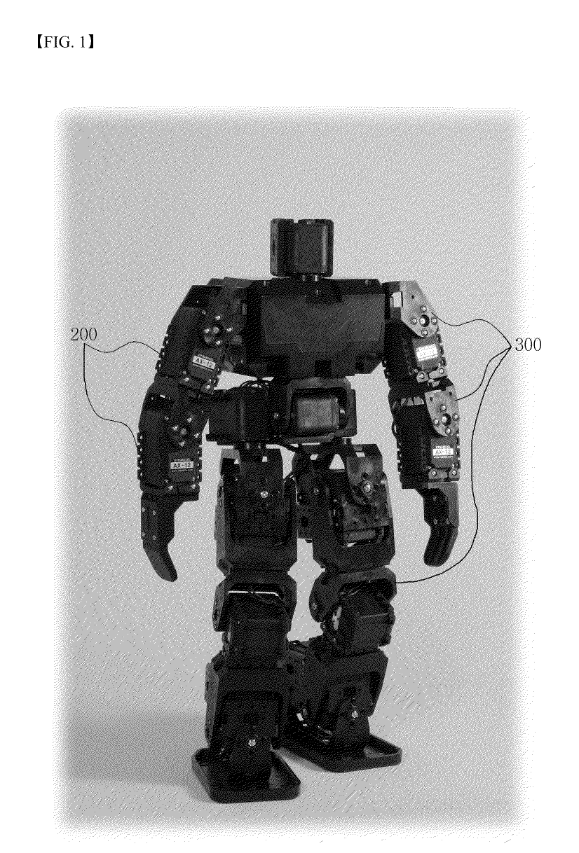

FIG. 1 illustrates a polyarticular robot comprising actuator modules of the present invention. The polyarticular robot is humanoid made in the form of a human. The humanoid in FIG. 1 comprises of a multiple of actuator modules 200 and coupling elements 300.

The universal connecting function of the actuator module of this invention results from the simple and effective combination structure of the actuator module 200 and the coupling element 300. Hereinafter, the combination structures of the actuator module 200 and various coupling elements 300 are explained with the accompanying drawings.

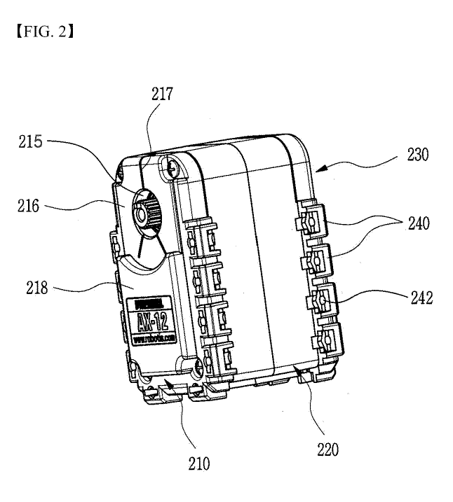

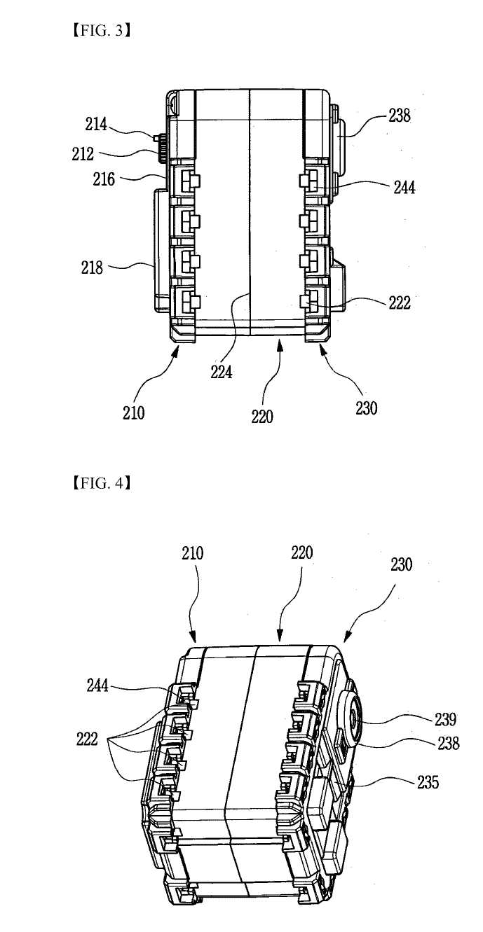

FIG. 2 is a first perspective view of an embodiment of the actuator module of the present invention. FIG. 3 is a side view of the actuator module shown in FIG. 2.

In FIGS. 2 and 3, the actuator module of the present invention 200 comprises of a first housing 210, a second housing 220, and a third housing 230. The first housing 210 is connected with the second housing 220 and the third housing 230 by 4 pieces of housing connecting bolts.

The first housing 210 covers mechanical parts of the actuator module. The first housing 210 comprises a aperture 215 through which a drive shaft 212 of the mechanical parts passes and a horn accepting surface 216 that has a lower height than that of a housing surface 218. A reference number 214 in FIG. 3 is a connecting protrusion formed at the end of the drive shaft 212. The second housing 220 comprises at least one bolt guide groove 222 to accommodate end part of a bolt that passes through an first aperture 242. A reference number 217 in FIG. 2 is a connection location line marked on the horn accepting surface 216. A reference number 224 in FIG. 3 is a center axis guide line formed on the outer surface of the second housing 220. A reference number 244 in FIG. 3 is a nut joining part to accommodate a nut. The third housing 230 comprises a bushing connecting part 238 to accommodate a bushing.

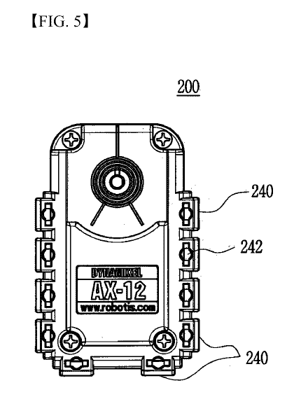

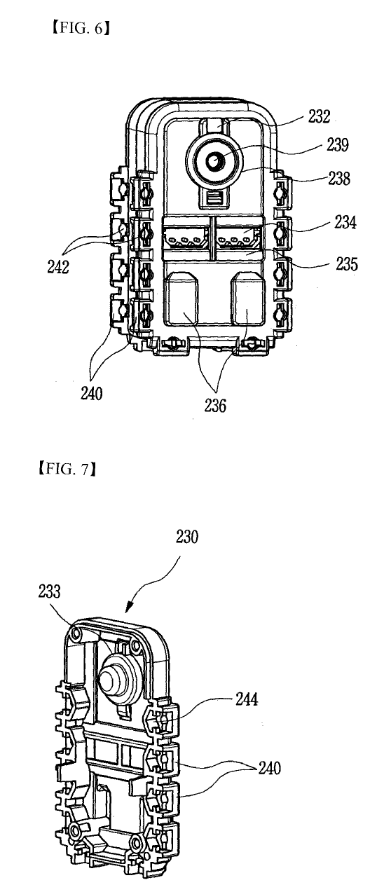

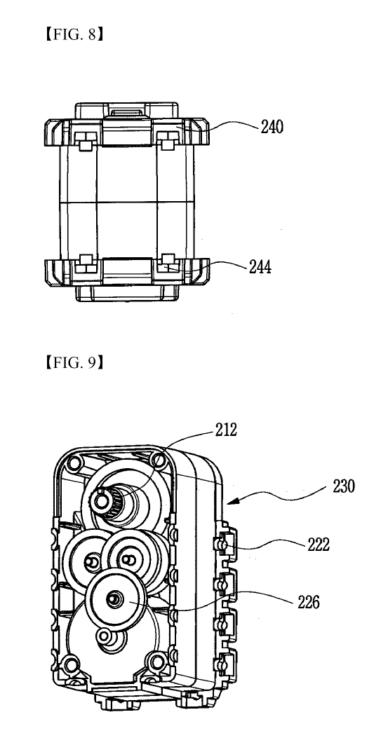

FIG. 4 is a second perspective view of the actuator module shown in FIG. 2. FIG. 5 is a front view of the actuator module shown in FIG. 2. FIG. 6 is a rear view of the actuator module shown in FIG. 2. FIG. 7 illustrates a third housing of the actuator module shown in FIG. 2. FIG. 8 is a bottom view of the actuator module shown in FIG. 2.

In FIGS. 4 and 5, the first housing 210 comprises 4 fixtures 240 formed on a left side and a right side of the first housing 210 and 2 fixtures 240 formed on a bottom of the first housing 210. The fixture 240 comprises an aperture 242 and a nut joining part 244 to accommodate a nut. The aperture 242 comprises a rectangular hole and a circular hole formed in the center of the rectangular hole. The aperture 242 supports bolt connection and wiring connections.

In FIGS. 4, 6, and 7, the third housing 230 comprises 4 fixtures 240 formed on a left side and a right side of the third housing 230 and 2 fixtures 240 formed on a bottom of the third housing 230. The fixture 240 comprises an aperture 242 and a nut joining part 244 to accommodate a nut. The aperture 242 comprises a rectangular hole and a circular hole formed in the center of the rectangular hole. The aperture 242 supports bolt connection and wiring connections.

In FIG. 6, the third housing 230 further comprises a connector installation part 235, a wiring guide part 236, and a bushing connecting part 238.

The connector installation part 235 in the middle part of the third housing is formed in the shape of rectangular holes. The connector installation part 235 prevents a wiring plug from protruding outward when the wiring plug is connected to a connector 234.

The wiring guide part 236 in the lower part of the third housing allows wires passing through the connector installation part 235 to be neatly guided to the lower of the third housing without protruding outside the actuator module. The bushing connecting part 238 is formed on the upper part of the third housing 230.

The bushing connecting part 238 accommodates bushing used to connect actuator modules 200 with coupling elements. Bolt holes 239 are formed in the center of bushing connecting parts 238. Bushing connecting parts 238 make the actuator module 200 and coupling elements to securely connect each other.

In FIG. 7, the third housing 230 further comprises a LED cover 233 to accommodate a LED 232 (shown in FIG. 6). The LED 232 shows an operating status of the actuator module. The third housing 230 comprises 4 fixtures 240 formed on a left side and a right side of the third housing 230 and 2 fixtures 240 formed on a bottom of the third housing 230. The fixture 240 comprises a nut joining part 244 to accommodate a nut.

In FIG. 8, the first housing 210 comprises 2 fixtures 240 formed on a bottom of the first housing 210. The third housing 230 comprises 2 fixtures 240 formed on a bottom of the third housing 230. The fixture 240 comprises a nut joining part 244 to accommodate a nut.

FIG. 9 is an internal view of the actuator module shown in FIG. 2.

The actuator module consists of mechanical parts such as motor, gear box 226, shaft 212, etc. and circuit parts such as sensor, microprocessor, network interface, etc. A reference number 222 in FIG. 9 is a bolt guide groove to accommodate end part of a bolt that passes through an aperture 242 (shown in FIG. 6).

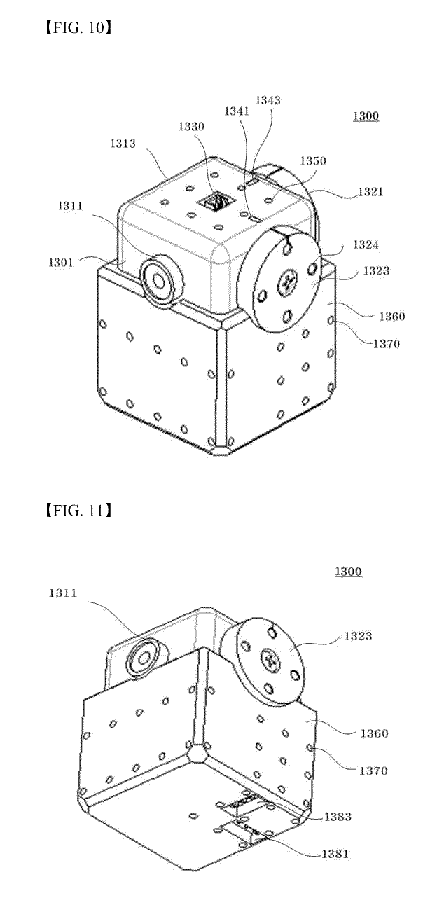

FIG. 10 is a first perspective view seen from the top of another embodiment of an actuator module of the present invention. FIG. 11 is a second perspective view seen from the bottom of the actuator module shown in FIG. 10.

In FIGS. 10 and 11, the actuator module 1300 with 2 degrees of freedom comprises an upper housing 1301, a first horn 1321, a second horn 1323, a second status display part 1341, a first status display part 1343, and a lower housing 1360.

The upper housing 1301 forms into a shape of hexahedron that is shorter than the lower housing 1360 in height, length, and width. The upper housing 1301 comprises a first bushing connecting part 1311, a second bushing connecting part 1313, an upper port 1330, and an first additional installation holes 1350.

The first bushing connecting part 1311 connects to a bushing to accommodate a rotational axle of a fifth coupling element (not shown in FIGS. 10 and 11). The second bushing connecting part 1313 connects to a bushing to accommodate a rotational axle of a sixth coupling element (not shown in FIGS. 10 and 11).

The first horn 1321 and the second horn 1323 are formed in a round board shape, and connect to a coupling element by connecting four connecting holes 1324 with bolts.

The first status display part 1343 shows the driving status or rotation status of fifth coupling element (not shown in FIGS. 10 and 11) connected with the first horn 1321 and the first bushing connecting part 1311. The first status display part 1343 may be an LED device. The second status display part 1341 shows the driving status or rotation status of a sixth coupling element (not shown in FIGS. 10 and 11) connected with the second horn 1323 and the second bushing connecting part 1313. The second first status display part341 may be an LED device.

The upper port 1330 is an independent port for supplying power or control signals to outside, and it is formed on the top of the upper housing 1301.

The first additional installation holes 1350 are formed on the outer surface of the upper housing 1301. The first additional installation holes 1350 are used to additionally connect bolts or fix cables.

The lower housing 1360 comprises second additional installation holes 1370, a first lower port 1381, and a second lower port 1383.

The second additional installation holes 1370 are formed on the outer surface of the lower housing 1360. The second additional installation holes 1370 are used to additionally connect bolts or fix cables.

The first lower port 1381 is formed on the lower part of the lower housing 1360, and supplies electric power or control signals to outside. The lower port 2 1383 is formed on the bottom part of the lower housing 1360, and supplies electric power or control signals to outside.

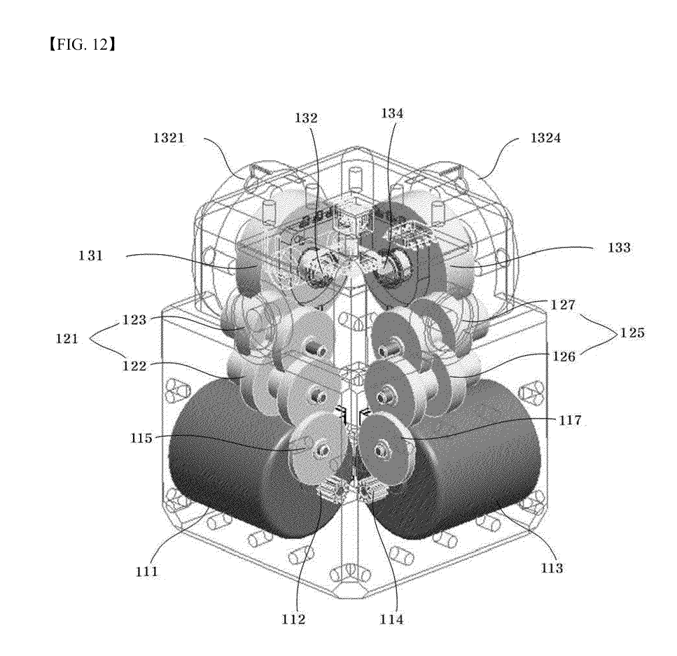

FIG. 12 shows internal mechanisms of the actuator module shown in FIG. 10.

The actuator module with 2 degrees of freedom comprises a first motor 111, a first rotation axle gear 112, a second motor 113, a second rotation axle gear 114, a first spur gear 115, a second spur gear 117, a first drive connecting part 121, a second drive connecting part 125, a first horn gear 131, a second horn gear 133. The first rotation axle gear 112, the first spur gear 115 and the first drive connecting part 121 form a first gear set. The second rotation axle gear 114, the second spur gear 117 and the second drive connecting part 125 form a second gear set.

The first motor 111 is a unit to deliver the driving power to rotate the first drive shaft 132 connected to a first horn 1321. The first rotation axle gear 112 is formed on the rotation axle of the first motor 111, and delivers the driving power of the first motor 111 to the first spur gear 115.

The second motor 113 is a unit to deliver the driving power to rotate the second drive shaft 134 connected to a second horn 1324. The second rotation axle gear 114 is formed by the rotation axle of the second motor 113, and delivers the driving power of the second motor 113 to the second spur gear 117.

The first spur gear 115 comprises a sawtooth part and a rotation axle part. The sawtooth part and the rotation axle part are all formed in the shape of sawtooth. The sawtooth part of the first spur gear 115 receives a driving power from the sawtooth part of the first rotation axle gear 112 and the rotation axle part of the first spur gear 115 delivers the driving power from the first rotation axle gear 112 to a first drive connecting gear 122.

The second spur gear 117 comprises a sawtooth part and a rotation axle part. The sawtooth part and the rotation axle part are all formed in the shape of sawtooth. The sawtooth part of the second spur gear 117 receives a driving power from the second rotation axle gear 114 and the rotation axle part of the second spur gear 117 delivers the driving power from a second rotation axle gear 114 to a third drive connecting gear 126.

The first drive connection part 121 comprises a first drive connecting gear 122 and a second drive connecting gear 123. The first drive connecting gear 122 receives the driving power from the rotation part of the first spur gear 115 and delivers it to the second drive connecting gear 123. The first drive connecting gear 122 comprise two sawtooth parts and a rotation axle part. The two sawtooth parts and the rotation axle part form a single set, and the front part and the rear part can be distinguished.

The sawtooth part formed on the front part of a first drive connecting gear 122 receives a first driving power from the spur gear 115. A rotation axle part of the front part, a sawtooth part of rear part and a rotation axle part of the rear part of the first drive connecting gear 122 sequentially deliver the driving power from a first rotation axle gear 112 to a second connecting gear 123.

The second drive connecting gear 123 receives a driving power from the first drive connecting gear 122 and delivers it to a first horn gear 131. The second drive connecting gear 123 comprise two sawtooth parts and a rotation axle part. The two sawtooth parts and the rotation axle part form a single set, and the front part and rear part can be distinguished.

A sawtooth part and a rotation axle part formed on the front part of a second drive connecting gear 123 and a sawtooth part formed on the rear part of the second drive connecting gear 123 sequentially receive a driving power from the drive connecting gear 1a 122 and a first horn gear 131.

The second drive connection part 2 125 comprises drive a third connecting gear 126 and a fourth drive connecting gear 127. The third drive connecting gear 126 receives the driving power from the rotation part of a second spur gear 117 and delivers it to the fourth drive connecting gear 127. The third drive connecting gear 126 comprise two sawtooth parts and a rotation axle part. The two sawtooth parts and the rotation axle part form a single set, and the front part and rear part can be distinguished.

The sawtooth part formed on the front part of a third drive connecting gear 126 receives a driving power from the second spur gear 117. A rotation axle part of the front part, a sawtooth part of rear part and a rotation axle part of the rear part sequentially deliver the driving power from the second spur gear 117 to the fourth connecting gear 127.

The fourth drive connecting gear 127 receives a driving power from the third drive connecting gear 126 and delivers it to a second horn gear 133. The fourth drive connecting gear 127 comprise two sawtooth parts and a rotation axle part. The two sawtooth parts and the rotation axle part form a single set, and the front part and rear part can be distinguished.

A sawtooth part and a rotation axle part formed on the front part of a fourth drive connecting gear 127 and a sawtooth part formed on the rear part of the third drive connecting gear 2b 127 sequentially receive a driving power from the third drive connecting gear 126. A rotation axle part formed on the rear part of the fourth drive connecting gear 127 delivers the driving power from the third drive connecting gear 126 to a second horn gear 133.

The first horn gear 131 receives a driving power from the second drive connecting gear 123 and rotates the first horn 1321. The first horn gear 131 receives the driving power through the rotation axle part formed on the rear part of the second drive connecting gear 123, and delivers it to the first horn 1321 through the first drive shaft 132.

The second horn gear 133 receives a driving power from a fourth drive connecting gear 127 and rotates the second horn 1324. The second horn gear 2 133 receives a driving power through the rotation axle part formed on the rear part of the fourth drive connecting gear 127, and delivers it to the second horn 1324 through the second drive shaft 134.

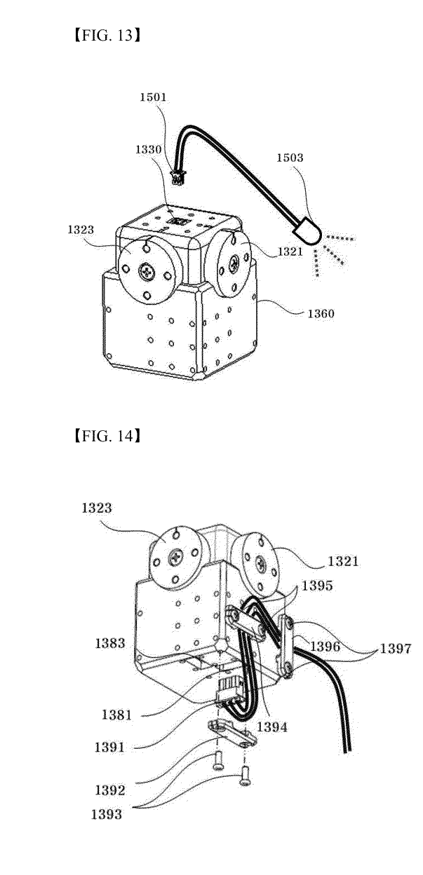

FIG. 13 shows the upper port of the actuator module shown in FIG. 10. The upper port 1330 is an independent port for supplying electric power or control signals to outside, and as shown in the drawings, it connects to the port connector 1501 and supplies power or control signals to an external LED 1503.

FIG. 14 shows wiring arrangement of the actuator module shown in FIG. 11. For neatly organizing the wires connected to a first lower port 1381, a connector connecting part 1391, a first fixing bar 1392, a first bolt part 1393, a second fixing bar 1394, a second bolt part 1395, a third fixing fixed bar 1396 and a third bolt part 1397 are required.

The connector connecting part 1391 is protruded for connection with the first lower port 1381, and it is wired inside. The first fixing bar 1392 is a fixing unit for securing the connector connecting part 1391 after the connector connecting part 1391 has been inserted to first lower port 1381, and it comprises at both ends two perforated holes for the first bolt part to pass through.

The first bolt part 1393 is fixed on the second additional installation holes 1370 formed on a bottom of the lower housing 1360 through the perforated holes formed on the first fixing bar 1392.

The second fixing bar 1394 is formed in a shape of a horizontal bar on the surface where the first horn 1321 is formed in the lower housing 1360, and it is a fixed unit to secure the wires connected to the connector connecting part 1391 and has at both ends two perforated holes for the second bolt part 1395 to pass through.

The second bolt part 1395 secures the second fixing bar 1394 on an second additional installation hole 1370 formed on the surface where the first horn 1321 of the lower housing 1360 was formed through the perforated holes formed on the second fixing bar 1395.

The third fixing bar 1396 is formed in a shape of a vertical bar on the surface where the first horn 1321 is formed in the lower housing 1360, and it is a fixed unit to secure the wires connected to the second connector connecting part 1394 and has at both ends two perforated holes for the third bolt part 1397 to pass through.

The third bolt part 1397 secures the third fixing bar 1396 on an second additional installation hole 1370 formed on the surface of the lower housing 1360 through the perforated holes formed on the third fixing bar 1396.

In FIG. 14 the second lower port 1383 was omitted and it was explained with the first lower port 1381 as the reference, but it is evident that a fixing device to deal with the second lower port 1383 can be formed in a similar way.

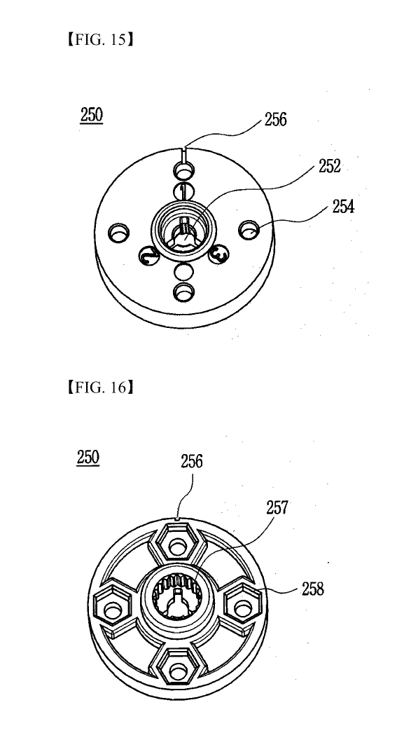

FIGS. 15 and 16 show a top view and a bottom view of a horn 250 respectively that connects to a drive shaft 212 (shown in FIG. 3). Connecting reference lines 256 that configure the connecting locations with the drive shaft 212 are marked on the top and side of the horn 250, and the bottom side of the horn 250 comprises a nut joining part 258 that accommodates a nut when connecting the horn 250 with the coupling element with a bolt. A shaft connecting hole 252 to accommodate the drive shaft 212 is formed in the center of the horn 250 and screw threads 257 are formed on the lower part of a shaft connecting hole 252 for connection with the drive shaft 212. Three grooves with 120 degrees in angle are formed on the surface of the outer diameter of the shaft connecting hole 252 that is a round shaped aperture, and when connecting the horn 250 with the drive shaft 212 at least one of these three grooves must connect with the connecting protrusion 214 (shown in FIG. 3) and this prevents the connection of the horn 250 with the drive shaft 212 in an incorrect angle by mistake.

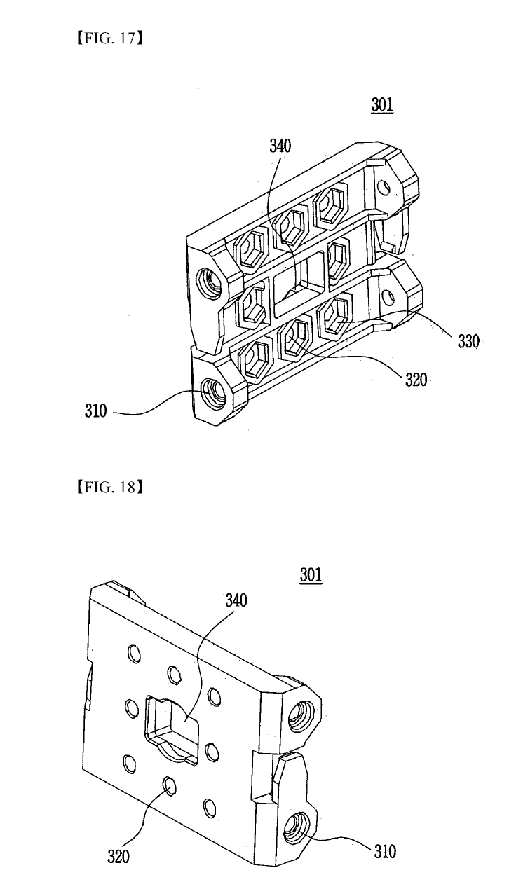

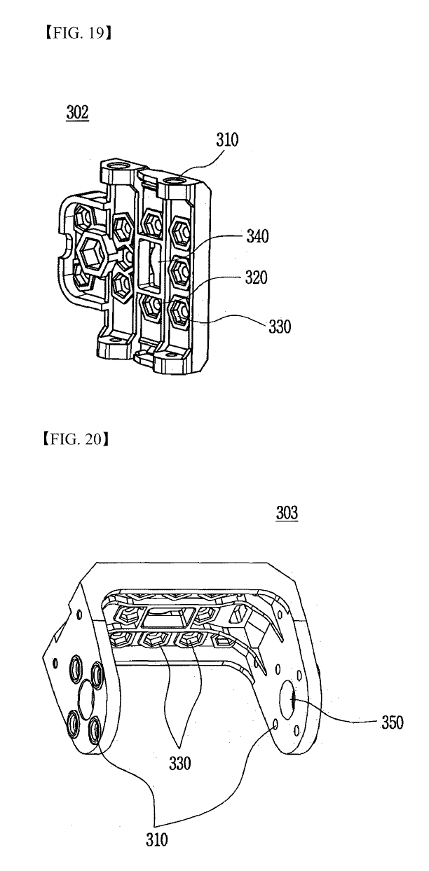

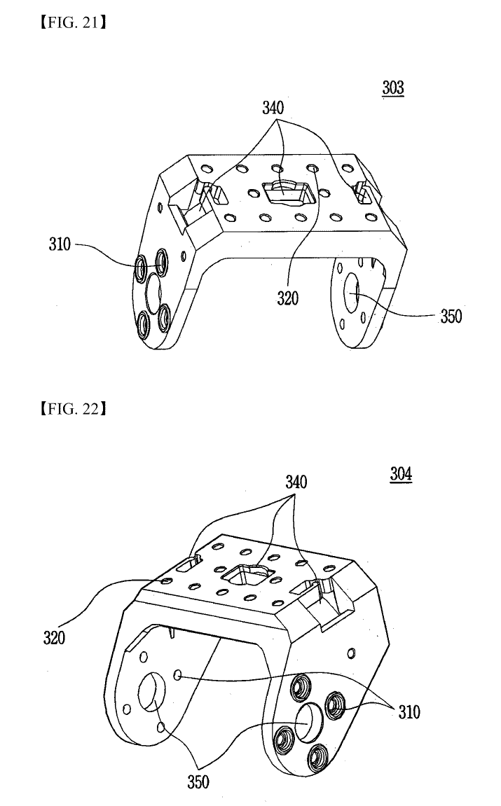

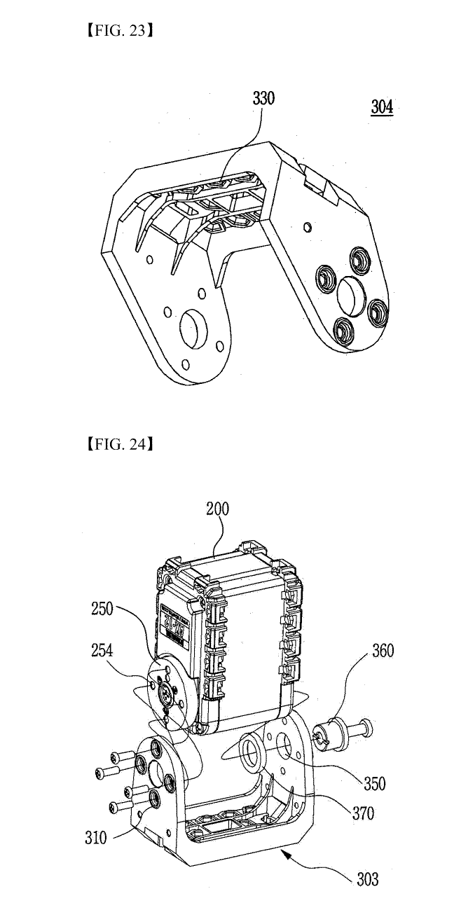

FIGS. 17 and 18 show a perspective view of a first coupling element that connects to the actuator module of the present invention. FIG. 19 shows a perspective view of a second coupling element that connects to the actuator module of the present invention. FIGS. 20 and 21 show a perspective view of a third coupling element that connects to the actuator module of the present invention. FIGS. 22 and 23 show a perspective view of a fourth coupling element that connects to the actuator module of the present invention.

First, second, third and fourth coupling elements 301, 302, 303, 304 all have hooks 340 in the center and a left side and a right side in common, and comprise fixtures on the left side and the right side of the coupling element with first bolt holes 310 that allow the bolt heads to be inserted when connecting with other coupling elements or actuator modules. Meanwhile, the left and right sides of first, second, third and fourth coupling elements 301, 302, 303, 304 having hooks 340 through which the wires to pass are each obliquely formed at a certain distance and angle maintain the wires that pass through the hooks 340 to stay in contact with the sides of the coupling element and not to protrude outward.

Also, a second bolt hole 320 and a nut joining part 330 are formed to connect with other coupling elements or actuator modules on the center plate of the first, second, third and fourth coupling elements 301, 302, 303, 304. Especially, on the left and right sides of the fixtures of the third coupling element 303 and the fourth coupling element 304, an anchor insertion part 350 is additionally formed to connect with an actuator on an extended axle of the drive shaft of the actuator.

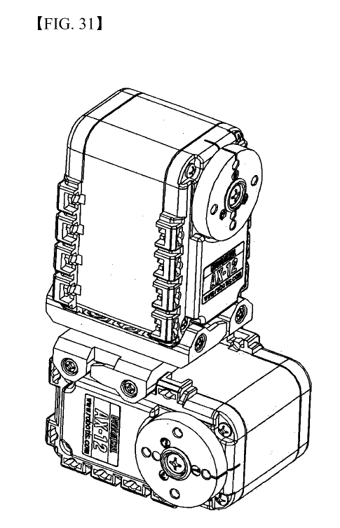

In FIG. 24 or 31, connecting relationships between coupling elements and other coupling element or actuator modules 200 are explained.

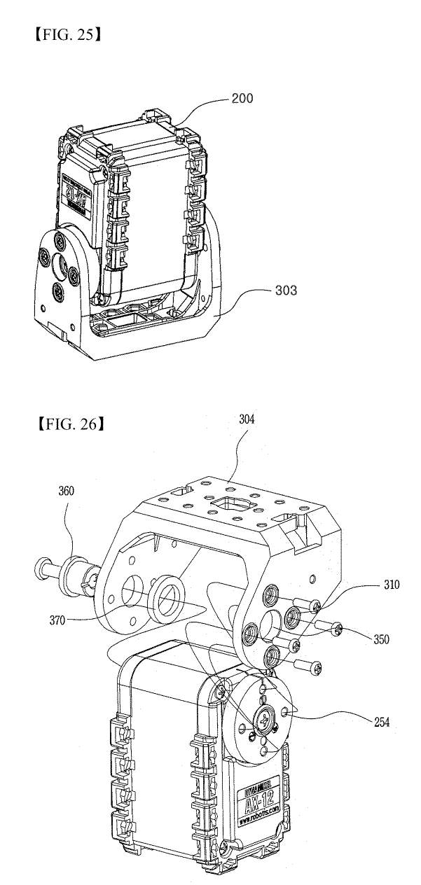

FIGS. 24 and 25 show a connecting relationship between the actuator module shown in FIG. 2 and the third coupling element shown in FIGS. 20 and 21.

In FIG. 24, bolts that passed through first bolt holes 310 formed on the left fixture of a third coupling element 303 pass through the bolts holes 254 formed on a horn 250, and connect with the nut to accommodate a nut joining part formed in the horn 250, and thereby the left fixture of the third coupling element 303 securely couples the horn 250.

Also, when connecting the right fixture of thea third coupling element 303 with an actuator 200, an anchor 360 is inserted in an anchor insertion part 350 formed on the right fixture of the third coupling element 303, and a bushing 370 is inserted between the right fixture and the bushing connecting part 238 of the actuator. The bolt that passed sequentially through the anchor 360, the anchor insertion part 350, the bushing 370 sequentially connects with the nut accommodated in the LED cover 233 (shown FIG. 7) after passing through the bolt hole 239 formed in the center of the bushing connecting part 238, and thus securely couples the right fixture of third coupling element 303 to the actuator module. The said plastic type bushing 370 which replaced steel type bushing contributed to the reduction of weight of the actuator modules.

The connecting status of the coupling element and the actuator module is shown in FIG. 25. The connecting characteristics between a coupling element and actuator modules of this invention is that the horns connected to the drive shaft functions as connecting means for the coupling elements, and the connection of coupling element with the actuator is performed through the bolt hole formed in the center of a bushing connecting part on the opposite side, resulting in the connection of coupling element and actuator at both ends of the shaft's prolongation thus enables a strong and secure connection compared to existing actuator combination structure that typically only allowed the connection on single side where the drive part was formed.

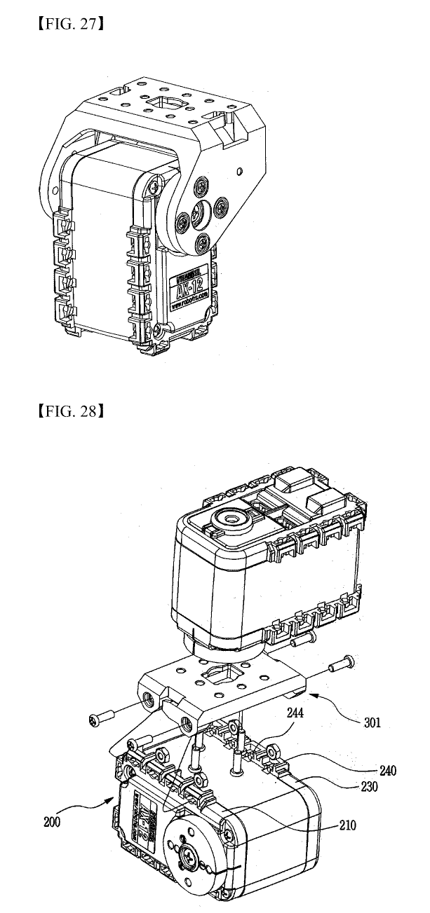

FIGS. 26 and 27 show a connecting relationship between the actuator module shown in FIG. 2 and the fourth coupling element shown in FIGS. 22 and 23. Since the connecting relationship of each part of the fourth coupling element 304 and each part of actuator 400 is identical to the case of the third coupling element 303 shown in FIGS. 24 and 25 other than the fact that left and right fixtures of the fourth coupling element 304 are sloped at an angle, detailed explanations will be omitted.

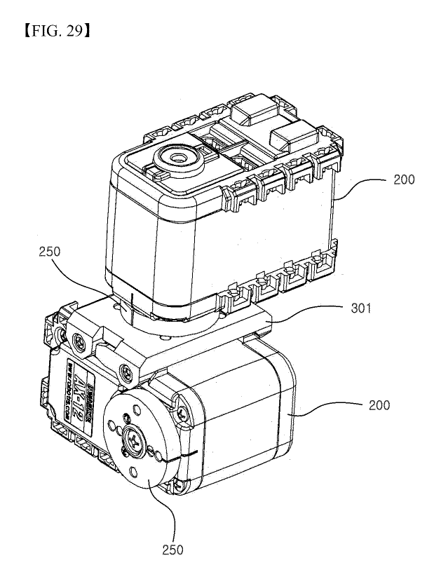

FIGS. 28 and 29 show a connecting relationship between two actuator module shown in FIG. 2 and the first coupling element shown in FIGS. 17 and 18. The inner distance between left and right side of fixtures of a first coupling element 301 almost matches the outer distance between fixtures 240 formed in symmetry at the edges of a first coupling element 210 and a third housing 230 of the actuator module, and thus allows the appropriate connection of the first coupling element 301 to the fixture 240 of the actuator. Also the sloped surface formed between the inner part and center plate of the first coupling element 301 is formed at the same angle as the sloped surface of the edge of fixtures 240 formed on the first housing and the third housing, and this increases the strength of the connection by making the first coupling element 301 to contact the actuator even closer. Also, FIG. 28 clearly shows the connecting method of the nut inside the nut joining part 244 formed inside the fixtures 240 of the first housing and the third housing.

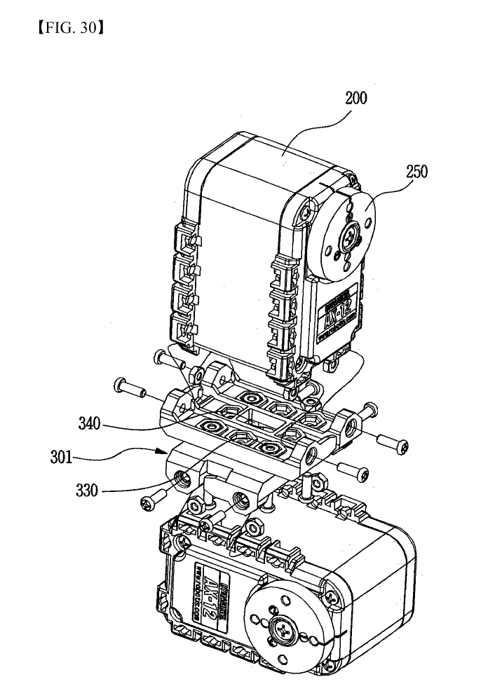

FIGS. 30 and 31 show a connecting relationship between two actuator module shown in FIG. 2 and two first coupling elements shown in FIGS. 17 and 18. FIGS. 30 and 31 show the connecting relationship and completed connection combination structure resulting from the connecting two first coupling elements with two actuator modules 200 without using the horn 250 when connecting the actuators. The first coupling elements 301 has 8 nut joining parts 330 formed in a square shaped arrangement, and this grants a form of standardization when connecting with other coupling elements. A reference number 340 in FIG. 30 is a hook of a first coupling element.

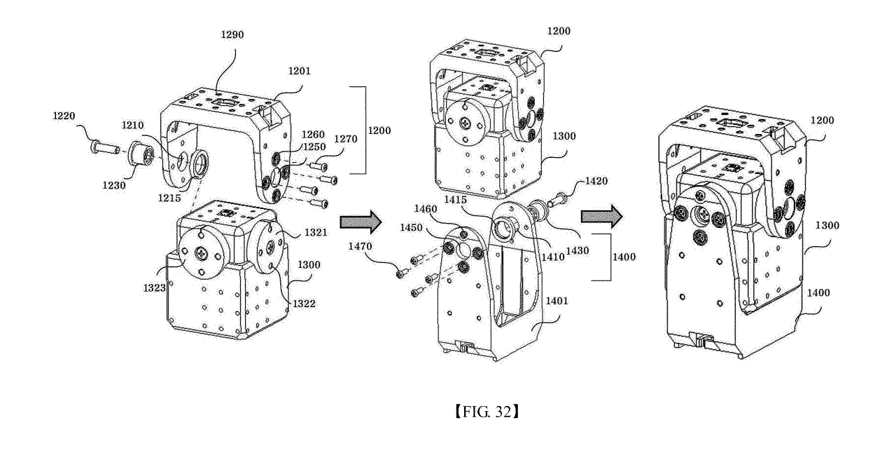

FIG. 32 shows a connecting relationship of an actuator module and a fifth coupling element and a sixth coupling element.

The fifth coupling element 1200 includes a fifth coupling element housing 1201, a first connecting hole 1210, a first rotation axle 1220, a first rotation axle guide section 1230, a second connecting hole 1250, a first bolt hole 1260 and a first bolt 1270. A reference number 1215 in FIG. 32 is a bushing.

The coupling element housing 5 1201 is formed in a Π shape-enlogated downward to both ends, and comprises a first connecting hole 1210 and a second connecting hole 1250.

The first connecting hole 1210 is located on the same line as a first bushing connecting section of an actuator module 1300, and is connected with the first rotation axle 1220.

The first rotation axle 1220 is connected to a first bushing connecting section of an actuator module 1300 after passing through a first rotation axle guide section 1230 and the first connecting hole 1210.

The first rotation axle guide section 1230 is hollow pipe shaped section that connects to the first connecting hole 1210, and provides rotation characteristic to the fifth coupling element 1200 along with the first rotation axle 1220.

The second connecting hole 1250 is located on the same line as the bolt that is connected with a first horn 1321. A first bolt hole 1260 is located on the identical line as the first connecting hole 1322 of the first horn 1321. A first bolt 1270 is connected to the first connecting holes 1260.

The sixth coupling element 1400 includes a sixth coupling element housing 1401, a third connecting hole 1410, a second rotation axle 1420, a second rotation axle guide section 1430, a fourth connecting hole 1450, a second bolt hole 1460, and a second bolt 1470. A reference number 1415 in FIG. 32 is a bushing.

The sixth coupling element housing 1401 is similar to the fifth coupling element housing 1201 but the length of both ends are different, and the third connecting hole 1410 and the fourth connecting hole 1450 are formed in the ends.

The third connecting hole 1410 is located on the identical line as a second bushing connecting section of an actuator module 1300, and is connected with the second rotation axle 1420.

The second rotation axle 1420 is connected to a second bushing connecting section of an actuator module 1300 after passing through a second rotation axle guide section 1430 and the third connecting hole 1410.

The second rotation axle guide section 1430 is hollow pipe shaped section that connects to the third connecting hole 1410, and provides rotation characteristic to the sixth coupling element 1400 along with the second rotation axle 1420.

The fourth connecting hole 1450 is located on the same line as the bolt that is connected with a second horn 1323. A second bolt hole 1460 is located on the identical line as the second connecting hole 1324 of the second horn 1323. A second bolt 1470 is connected to the second bolt hole 1460.

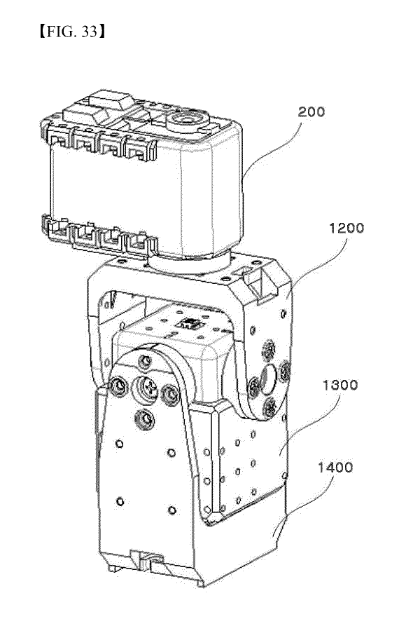

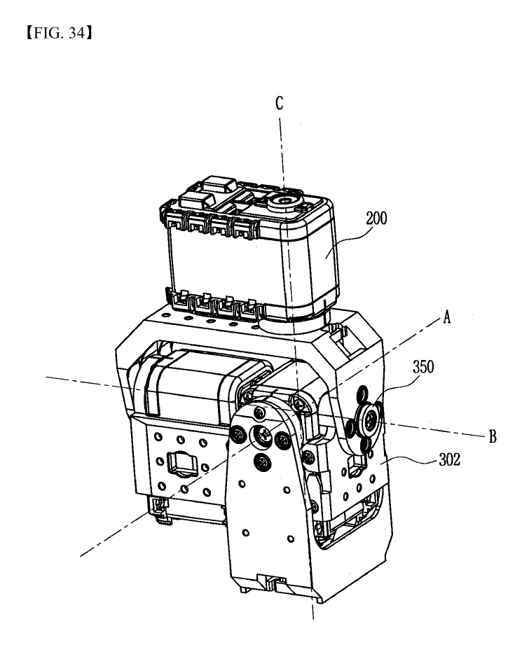

FIGS. 33 and 34 show a connecting relationship between the actuator module shown in FIG. 2 and the actuator module shown in FIG. 10.

In FIG. 33 an actuator module 200 is connected to a fifth coupling element 1200 and an actuator module 1300 with 2 degrees of freedom is connected to a sixth coupling element 1400.

In FIG. 34 three virtual center axes (A, B, C) of three actuator modules 200 also cross at a right angle and form an intersecting point. Thus, the actuator modules 200 and coupling elements of this invention can be always connected by the using the method of crossing the virtual center axes of actuator modules 200 at a right angle and forming an intersecting point, and such perpendicular connection not only increases the robustness of the connection, but also prevents the functional deterioration of the actuator module 200 by removing the load on the shaft of the actuator module 200 in any oblique direction, and it also enables effective design of actuator modules 200.

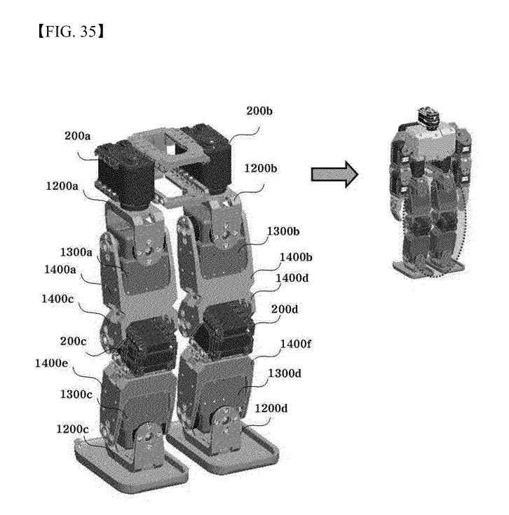

FIG. 35 illustrates a polyarticular robot formed by connecting the actuator module shown in FIG. 2 and the actuator module shown in FIG. 10.

Actuator modules 200a˜200d with universal combination structure in the embodiment 1, actuator modules 1300a˜1300d with 2 degrees of freedom in the second embodiment, fifth coupling elements 1200a˜1200d, and sixth coupling elements 1400a˜1400f are included in the formation of the polyarticular robot shown in FIG. 35, and accordingly for the knee joint where a single degree of freedom is required an actuator module in the first embodiment is applied, and in the case of the ankle joint where 2 degrees of freedom are required an actuator module in the second embodiment is applied to easily form the joints of the robot.

This invention was explained above using the preferred embodiments, but the fact that this invention is based on actuating mechanism with various forms that can be realized by connecting actuator modules that are specified and modularized. For example limiting the number of housing and only presenting known connection methods such as bolt-nut connection combination and explaining mainly in polyarticular robot application do not limit the idea of this invention to said embodiments only. For example, it should be evident to those skilled in the art that if an alternate connecting method such as rivet connections is chosen instead of the bolt-nut connection, the bolt holes, nut joining part, etc. of this invention can be changed appropriately. Accordingly the scope of this invention should be determined based on the attached patent claims.

What is claimed is:

1. An actuator module with universal combination structure comprising:
a housing to accommodate circuit parts and a mechanical parts; and
at least one first fixture formed on a side and a bottom of the housing,
wherein the each first fixture comprises a first aperture through which a bolt passes and a nut joining part to accommodate a nut.

2. The actuator module with universal combination structure of claim 1, further comprising:
a horn that is connected with a drive shaft of the mechanical parts,
wherein the horn comprises a shaft connecting hole to accommodate the drive shaft at the horn's center, and at least one groove that is formed on the outer surface of the shaft connecting hole to be connected with a connecting protrusion formed the end of the drive shaft.

3. The actuator module with universal combination structure of claim 2, wherein: the horn further comprises a connecting reference line formed on the top surface of the horn, at least one first bolt hole that passes through the horn, and at least one nut joining part formed on the bottom surface of the horn.

4. The actuator module with universal combination structure of claim 2, wherein: the housing comprises a first housing, a second housing connected with the first housing, and a third housing connected with the second housing,
wherein the first housing comprises a second aperture through which the drive shaft passes, the second housing comprises at least one bolt guide groove to accommodate the end part of a bolt that passes through the first aperture to be coupled to the nut installed in the nut joining part, and the third housing comprises a bushing connecting part to accommodate a bushing and a connector installation part that allows a connector to be installed.

5. The actuator module with universal combination structure of claim 4, wherein: the third housing further comprises a wiring guide part that guides wires to pass through the connector installation part.

6. The actuator module with universal combination structure of claim 1, further comprising: at least one coupling element that comprises at least one second fixture to be connected by a bolt with the first fixture formed on the side of the housing.

7. The actuator module with universal combination structure of claim 6, wherein: the coupling element further comprises at least one hook that allows wires to pass through.

8. The actuator module with universal combination structure of claim 6, wherein: the coupling element further comprises an anchor insertion part that allows an anchor to be inserted into.

9. An actuator module with universal combination structure having two degrees of freedom by a first drive shaft and a second drive shaft that is perpendicular to the first drive shaft.

10. The actuator module with universal combination structure of claim 9, comprising:
an upper housing that accommodates the first drive shaft, the second drive shaft, and first additional installation holes to be connected with bolts;
a lower housing that accommodates a first motor to drive the first drive shaft, a second motor to drive the second drive shaft, and second additional installation holes to be connected with bolts; and
first and second gear sets installed in the space inside the upper housing and the lower housing,
wherein the first gear set delivers driving power from the first motor to the first drive shaft and the second gear set delivers the driving power from the second motor to the second drive shaft.

11. The actuator module with universal combination structure of claim 10, wherein: the upper housing further comprises a first bushing connecting part to accommodate a first rotation axle of a first external coupling element, a second bushing connecting part to accommodate a second rotation axle of a second external coupling element, a first round board shaped first horn connected with a protruding end of the first drive shaft, and a second round board shaped second horn connected with a protruding end of the second drive shaft.

12. The actuator module with universal combination structure of claim 10, wherein: the upper housing further comprises an upper port that supplies electric power or control signals and is connected with a port connector.

13. The actuator module with universal combination structure of claim 10, wherein: the lower housing comprises a lower port that supplies electric power or control signals and is connected with a port connector.
